(19) United States
(12) Patent Application Publication
(10) Pub. No.: US 2025/0286564 A1
(43) Pub. Date: Sep. 11, 2025

(54) FOUNDATION MODEL FOR ERROR CORRECTION CODES AND LEARNING LINEAR BLOCK ERROR CORRECTION CODES

(71) Applicant: Ramot at Tel-Aviv University Ltd., Tel-Aviv (IL)

(72) Inventors: Yoni CHOUKROUN, Tel Aviv (IL); Lior WOLF, Tel Aviv (IL)

(73) Assignee: Ramot at Tel-Aviv University Ltd., Tel-Aviv (IL)

(21) Appl. No.: 19/071,967

(22) Filed: Mar. 6, 2025

Related U.S. Application Data
(60) Provisional application No. 63/562,091, filed on Mar. 6, 2024.

(51) Int. Cl. H03M 13/11

(52) U.S. Cl. CPC H03M 13/1105; H03M 13/1148

(57) ABSTRACT

The invention presents a universal foundation model for decoding error correction codes (ECC) and a learning-based method for linear block ECCs. The foundation model is trained on multiple codes using a code-invariant embedding, relative positional encoding from derived from parity-check matrices, and a size-invariant transformation to generate a robust noise prediction. A learned distance embedding derived from each code's Tanner graph modulates self-attention, allowing the system to handle both seen and unseen codes without retraining. Overall, this approach replaces specialized, code-specific decoders with a single efficient model, enabling more robust and scalable decoding of diverse error correction codes. The linear block learning component based on the Transformer architecture allows the differentiable training of the code via the Tanner graph connectivity derivation from the parity check matrix, and enables the effective and differentiable joint optimization of the code and of the neural decoder.

### RELATED APPLICATION(S)

This application claims the benefit of priority of U.S. Provisional Patent Application No. 63/562,091 filed on Mar. 6, 2024, the contents of which are incorporated herein by reference in their entirety.

### FIELD AND BACKGROUND OF THE INVENTION

As used herein, the term ECC means “error correction code”.

The present invention, optionally, relates to training and using neural networks to decode ECC codewords transmitted over transmission channels subject to interference and, more particularly, but not exclusively, to a universal neural framework capable of learning multiple linear block ECCs and generalizing to previously unseen codes without retraining.

Digital communication systems commonly rely on ECCs to ensure accurate data transmission over noisy channels. Optimal decoding strategies, although theoretically defined by the maximum likelihood rule, are computationally intractable for many practical code lengths. Consequently, developing efficient and scalable decoders remains an area of active investigation.

In recent years, various learning-based decoders have been proposed, often inspired by deep learning architectures. Examples include transformer-based methods that incorporate ECC-specific elements, such as code structures, directly into the neural network. These approaches have demonstrated performance improvements and reduced complexity in certain instances, and have been further explored within denoising diffusion frameworks for enhanced results.

A notable limitation of many current learning-based decoders is their specialized adaptation to a single code. Such designs do not readily translate to other codes or parameter settings, prompting a continued effort to identify more universal solutions.

Prior research on neural decoders is often categorized as either model-based, where parametric versions of classical algorithms like Belief Propagation (BP) are unfolded into neural networks, or model-free, which employs general network architectures such as fully connected layers or recurrent networks. Model-based methods typically retain a theoretical grounding but may impose rigid architectural constraints, whereas model-free approaches can struggle to learn the structure of the code. Transformer-based decoders have emerged as an additional direction, embedding signal features and combining them with code information through masked self-attention, and iterative denoising diffusion models built around these architectures have also shown further gains.

Neural decoder research generally focuses on short and moderate-length codes for three main reasons: (i) classical decoders are proven to reach the capacity of the channel for large codes, preventing any potential enhancement, (ii) the training and deployment of the existing neural decoding techniques are not trivial for large codes (i.e., thousands of bits), and (iii) the emergence of applications driven by the Internet of Things created the demand for optimal decoders of short to moderate codes.

### SUMMARY OF THE INVENTION

The present invention provides a universal approach to decoding ECCs via a neural network framework trained on diverse code families. By integrating code structure directly into a transformer-based architecture, the system can learn robust representations. This learned framework avoids the need for specialized decoders tailored to each individual ECC, thereby reducing complexity and enabling broader adoption in varied communication scenarios.

In some embodiments, the invention makes use of a foundation model, defined herein as a neural network model trained across multiple datasets or tasks—in this case, a range of ECCs—so that it can generalize to newly encountered codes without retraining.

In other embodiments, the invention makes use of a unified design and co-training of an ECC and a respective parametrized decoder.

According to an aspect of some embodiments of the present invention there is provided a system for decoding signals encoded with error correction codes, comprising a memory storing computer-readable instructions, and at least one processor configured to execute the instructions to input a first error correction code, comprising a first parity check matrix, into a pre-trained model having a transformer architecture, the pre-trained model having been trained on a plurality of error correction codes, generate a position-invariant high-dimensional representation of the first error correction code based on the pre-trained model, incorporate relative position information into the high-dimensional representation of the first error correction code based on the first parity check matrix; and predict a noise estimate for decoding based on the first parity check matrix and the high-dimensional representation of the first error correction code.

Optionally, generating a position-invariant high-dimensional representation of the first error correction code comprises applying a code-invariant initial embedding based on the pre-trained model to a representation derived from the first parity check matrix.

Optionally, incorporating relative position information into the high-dimensional representation of the first error correction code comprises constructing a Tanner graph from the first parity check matrix, computing a first distance matrix from the Tanner graph, and modulating the pre-trained model's self-attention map with the first distance matrix.

Optionally, predicting a noise estimate for decoding comprises applying a size-invariant transformation informed by the first parity check matrix to the refined high-dimensional representation of the first error correction code.

Optionally, the at least one processor is further configured to execute the instructions to receive a signal encoded with the first error correction code and decode the received signal, thereby generating a decoded output, wherein decoding the received signal comprises applying the noise prediction to the received signal.

Optionally, the code-invariant initial embedding is configured to be length-invariant.

Optionally, the size-invariant transformation is pre-trained on the plurality of error correction codes, each error correction code in the plurality having a block length less than a predetermined threshold.

Optionally, the size-invariant transformation comprises a learned aggregation function.

Optionally, each of the plurality of error correction codes is a linear code.

Optionally, a linear code is selected from the group comprising a Low-Density Parity Check (LDPC) code, a Polar code, a Reed Solomon code, and a Bose-Chaudhuri-Hocquenghem (BCH) code.

Optionally, decoding the received signal further comprises processing the received signal using a plurality of self-attention layers and feed-forward layers, and a plurality of normalization layers.

Optionally, decoding the received signal further comprises applying a distance embedding function, the distance embedding function being implemented as a fully connected neural network trained to learn a mapping from a number of paths in a Tanner graph to a scalar, the neural network comprising a multi-dimensional hidden layer and a plurality of nonlinear activation functions.

Optionally, the plurality of self-attention layers and feed-forward layers comprises at least 6 layers.

Optionally, the multi-dimensional hidden layer possesses at least 50 dimensions.

Optionally, the plurality of nonlinear activation functions comprises a ReLU activation function.

Optionally, the learned mapping is represented as a fixed tensor at inference time.

Optionally, the high-dimensional representation comprises at least 128 dimensions.

Optionally, the predetermined threshold is 150.

Optionally, each error correction code in the plurality of error correction codes comprises a generator matrix and a parity check matrix, and the pre-trained model is trained on the plurality of error correction codes using a plurality of differentiable masks, each differentiable mask being derived from the parity check matrix of a corresponding error correction code.

Optionally, the noise prediction is based on one or more of the following noise models: additive white Gaussian noise, Rayleigh fading, or burst-error channels.

Optionally, the system is applied to one or more of the following: 5G NR wireless communication networks, Wi-Fi, satellite communications, or low-power IoT devices.

According to an aspect of some embodiments of the present invention there is provided a method for decoding a signal encoded with an error correction code, the method comprising inputting a first error correction code, comprising a first parity check matrix, into a pre-trained model having a transformer architecture, the pre-trained model having been trained on a plurality of error correction codes, generating a position-invariant high-dimensional representation of the first error correction code based on the pre-trained model, incorporating relative position information into the high-dimensional representation of the first error correction code based on the first parity check matrix, and predicting a noise estimate for decoding based on the first parity check matrix and the high-dimensional representation of the first error correction code.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a visual representation of select Hamming(7,4) code properties, as found in the prior art;

FIG. 2 is an illustration of a foundational transformer model architecture, according to some embodiments of the invention;

FIG. 3 is an illustration of an end-to-end communication system based on a predetermined plurality of ECCs, according to some embodiments of the invention; and

FIG. 4 is an illustration of an end-to-end communication system based on a learned linear block ECC, according to some embodiments of the invention.

### DESCRIPTION OF SPECIFIC EMBODIMENTS OF THE INVENTION

The present invention, optionally, relates to training and using neural networks to decode ECC codewords transmitted over transmission channels subject to interference and, more particularly, but not exclusively, to a universal neural framework capable of learning multiple linear block ECCs and generalizing to previously unseen codes without retraining.

The system described hereinbelow enables decoding of algebraic block codes in a code-invariant and size-invariant manner by leveraging self-attention mechanisms modulated through learned representations of a parity check matrix.

The method described hereinbelow is particularly useful for scenarios requiring efficient and adaptive decoding of multiple ECC families.

The present invention offers several notable advantages and improvements, including the ability to generalize across unseen codes and code lengths through pretraining on a diverse set of codes, a considerable reduction in the number of model parameters compared to conventional deep-learning-based decoders while achieving state-of-the-art performance, and the potential for deployment in embedded communication systems to reduce storage and computational overhead associated with traditional decoders.

In some embodiments, the system implements a foundation model for ECC decoding. This model is pre-trained on a diverse set of ECCs and learns a universal representation that generalizes across multiple code families, allowing for zero-shot generalization to previously unseen ECCs without requiring retraining.

In other embodiments, the system includes a learned linear block ECC framework, where both the encoder and decoder are jointly optimized using a differentiable training process. This approach enables the discovery of novel block codes tailored to specific noise conditions and hardware constraints, surpassing classical hand-designed generator matrices.

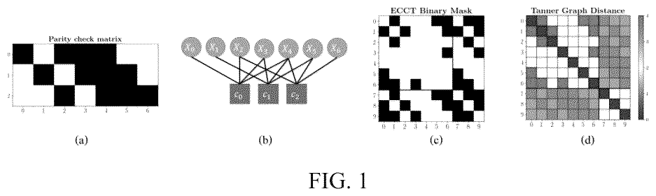

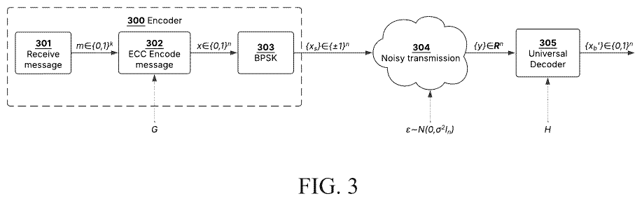

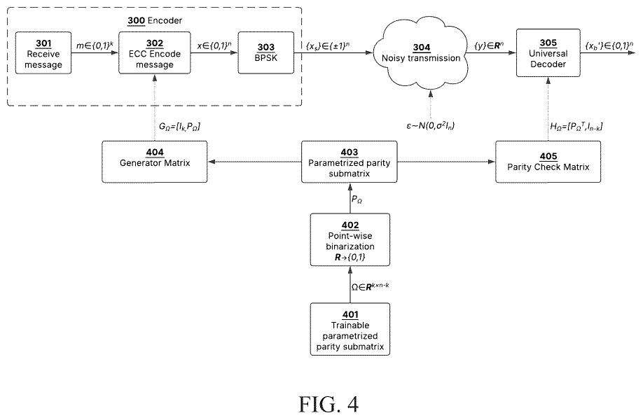

For purposes of better understanding some embodiments of the present invention, as illustrated in FIGS. 3-4 of the drawings, reference is first made to a visual representation of select Hamming(7,4) code properties as illustrated in FIG. 1.

FIG. 1(a) illustrates the parity check matrix H of a Hamming(7,4) code, wherein each row corresponds to a parity-check constraint and each column corresponds to a code symbol. The parity check matrix H serves as a fundamental representation of a code's error-checking properties.

FIG. 1(b) illustrates the Tanner graph corresponding to the parity check matrix illustrated in FIG. 1(a). In this graph, variable nodes represent the code symbols and check nodes represent the parity-check constraints, with edges connecting nodes where the corresponding entry in the parity check matrix is nonzero.

FIG. 1(c) illustrates a binary masking function g (H): {0,1}^{(n-k)×k}→{−∞, 0}^{(2n-k)×(2n-k)}, derived from the structure of the parity check matrix, which may be used to restrict the self-attention mechanism by allowing interactions only between nodes adjacent nodes (distance is 1) and secondary neighbors (distance is 2) in the Tanner graph illustrated in FIG. 1(b).

FIG. 1(d) illustrates the distance matrix [symbol] (H)∈ [symbol] ^{(2n-k)×(2n-k)} computed from the Tanner graph illustrated in FIG. 1(b). Each element (i, j) in the distance matrix represents the shortest-path distance between the nodes i and j in the graph.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

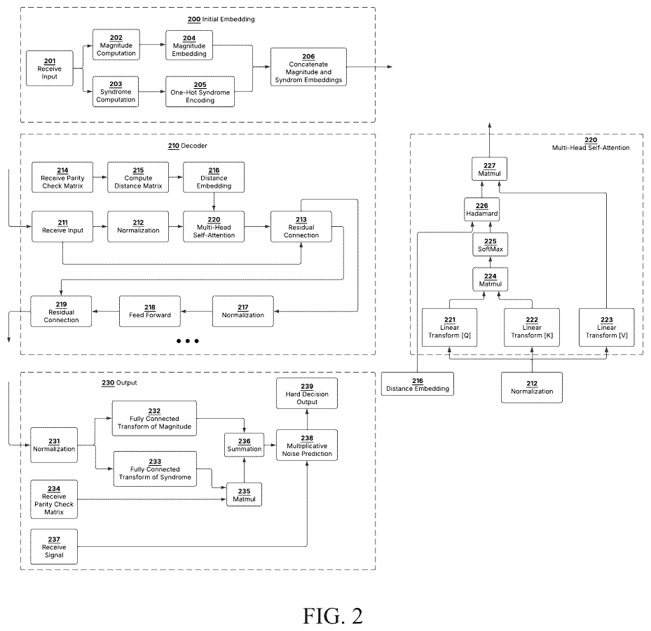

Referring now to the drawings, FIG. 2 illustrates a foundational transformer model architecture. According to some embodiments of the invention, a single embedding corresponds to each magnitude element, and two embeddings correspond to each binary syndrome element, wherein y is the model input, |y| comprises magnitude of the model input, and s(y)=Hy_{b}=H (0.5(1−sign (y)))∈{0,1}^{n-k} comprises binary code syndrome of the model input, ensuring that the input representation is invariant both to a specific ECC and its length, facilitating generalization across diverse code families.

Optionally, a positional embedding Φ comprises a plurality of d-dimensional embeddings {ϕᵢ}ᵢ₌₁^{2n-k}∈ [symbol] ^{d}, wherein

$${ϕ}_{i} = \{ \begin{matrix}\vert {y}_{i} \vert {W}_{M} & if i \leq n \\ {W}_{{( s ( y ) )}_{i - n + 1}}^{S} & i > n\end{matrix} , and$$

wherein {W_{M}, W₀^{S}, W₁^{S}}∈ [symbol] ^{d} denote the magnitude encoding and one-hot encoding of the binary syndrome elements, respectively, and wherein (s(y))ⱼ denotes the j-th element of the syndrome vector.

Optionally, the transformer model computes initial embeddings 200, and propagates them through a multi-layer decoder 210 towards an output module 230 to generate a final noise prediction.

Optionally, an initial embedding 200 of the transformer model comprises receiving an input 201, computing a magnitude 202 of the input and the binary code syndrome 203 of the input, computing a d-dimensional vector 204 for the magnitude, thereby producing the magnitude embedding, computing a d-dimensional one-hot encoding 205 of the syndrome, thereby producing the syndrome embedding, and concatenating 206 magnitude and syndrome embeddings, thereby producing a plurality of three d-dimensional parameters.

Optionally, a decoder 210 of the transformer model comprises a concatenated plurality of N decoding layers, wherein each decoding layer comprises a multi-head self-attention block 220 and a feed-forward block 218, interleaved with d-dimensional normalization blocks 212, 217 and residual connection blocks 213, 219. Optionally, the number of layers N=6. Optionally, dimensionality d=128.

Optionally, a decoder layer receives 211 an input, receives 214 a parity check matrix H corresponding to the ECC on which the decoder is configured to be conditioned, computes 215 a distance matrix [symbol] (H) derived from the parity check matrix H, and applies a parametrized learned mapping function ψ: [symbol] → [symbol] to the distance matrix, thereby producing a distance embedding 216. Optionally, the mapping function ψ is a learned integer-to-scalar mapping for mapping values 1 . . . 10, wherein 10 is the maximal distance encountered in a Tanner graph.

Optionally, a self-attention module 220 comprises a self-attention map A_{H}(Q, K, V) modulated by values of the distance embedding 216, thereby incorporating positional information into the self-attention mechanism, wherein Q,K,V are the respective projection matrices.

Optionally, the self-attention module comprises the following expression:

$${A}_{H} ( Q , K , V ) = ( softmax ( \frac{Q {K}^{T}}{√ d} ) ⊙ ψ ( 𝒢 ( H ) ) ) V$$

Optionally, a self-attention map receives a normalized input from a normalization layer 212; applies linear transformations 221, 222, 223 to the input, thereby generating the Q, K, V matrices, respectively; performs a dot product operation 224 on the Q and K matrices; applies 225 a softmax operation to the result of the matrix multiplication to produce attention weights; computes 226 a Hadamard product of the softmax output and the distance embedding 216, thereby modulating the attention weights, and applies 227 a matrix multiplication operation to the modulated attention weights and the V matrix, thereby producing the self-attention output. The self-attention module 220 integrates relative positional information by applying the learned function ψ to the Tanner graph distance matrix [symbol] (H). This function modulates the attention weights by assigning different importance levels based on the shortest-path distances between nodes in the Tanner graph. As a result, closer nodes exert a stronger influence, improving the model's ability to respect the structural constraints of ECCs during decoding.

Optionally, an output module 230 processes a learned embedding by separately transforming a magnitude component and a syndrome component of the embedding. The output module receives a normalized input from a normalization layer 231 and applies connected transformations 232 and 233, wherein a first transformation 232 is applied to the magnitude component and a second transformation 233 is applied to the syndrome component. The output module 230 subsequently aggregates 235 the transformed syndrome component based on a configured parity check matrix 234, resizing the syndrome representation from n−k embeddings to n embeddings. The output module 230 subsequently combines the n transformed magnitude elements and the n aggregated syndrome elements via a summation operation 236, producing an updated representation. The output module 230 subsequently applies to the updated representation a dimensionality reduction operation from d dimensions to 1 dimension, thereby producing a noise prediction, comprising the following expression:

$$\hat{\tilde{ε}} = ( {ϕ}_{0 , M} {W}_{M} + {H}^{T} ( {ϕ}_{0 , S} {W}_{S} ) ) {W}_{d \to 1}$$

wherein ϕ₀∈ [symbol] ^{(2n-k)×d} is the final transformer embedding, W_{S}, W_{M}∈ [symbol] ^{d×d} are learnable affine transformations, ϕ_{0[1:n]}=ϕ_{0,M}∈ [symbol] ^{n×d} is the magnitude part of the final transformer embedding, ϕ_{0[n+1:2n-k]}=ϕ_{0,s}∈ [symbol] ^{(n-k)×d} is the syndrome part of the final transformer embedding, and W_{d→1} is the final embedding shrinkage. The output module 230 subsequently modulates a received signal 237 with the predicted noise via a multiplicative noise prediction stage 238, and processes the multiplication result through a hard decision operation 239, thereby generating a decoded output. The proposed aggregation enables both (i) code-awareness in the sense that the aggregation is induced by a parity check matrix corresponding to a configured ECC, and (ii) code-invariance in the sense that the aggregation is invariant to a code size and can be performed with an arbitrary ECC.

Optionally, the training objective is the cross-entropy function with the goal of learning to predict the binary multiplicative noise \tilde{ε}=bin(\tilde{ε}ₛ)=bin(\tilde{ε}⊙xₛ), wherein \tilde{ε}ₛ is the soft multiplicative noise, the loss for a single received word y comprises: L=−Σᵢ₌₁ⁿ\tilde{ε}ᵢ log(ƒ_{θ}(y))+(1−\tilde{ε}ᵢ)log(1−ƒ_{θ}(y)), and thereby the estimated hard-decoded codeword comprises x_{b}′=bin (sign(ƒ_{θ}(y)⊙y).

Optionally, the Adam optimizer is utilized for training the foundational model. Optionally, the optimizer is configured to use 512 samples per minibatch, 1000 minibatches per epoch and 300 epochs for training. Optionally, the optimizer is configured to use 1024 samples per minibatch, 1000 minibatches per epoch and 1000 epochs for training. Optionally, the learning rate is initialized at 10⁻⁴ and coupled with a cosine decay scheduler down to 10⁻⁶ at the end of the training.

Optionally, the plurality of codes utilized for training comprises a plurality of linear codes, which satisfy the property that the sum of any two codewords in the code is also a valid codeword. Linear block codes are widely utilized in digital communication systems due to their structured algebraic properties, which allow for efficient encoding and decoding.

Optionally, the plurality of codes utilized for training comprises a plurality of linear block codes, comprising at least Low-Density Parity Check (LDPC) codes, Polar codes, Reed-Solomon codes, and Bose-Chaudhuri-Hocquenghem (BCH) codes. These code families are commonly used in modern communication standards such as 5G, deep-space communication, and storage systems. Each of these codes has distinct structural properties, and the model is designed to generalize across them by learning from a diverse training set that includes multiple code types.

Optionally, codes with a length below a predetermined threshold are utilized for training exclusively. Optionally, the predetermined threshold is 150 bits.

In some embodiments, the system is implemented using dedicated hardware to enable efficient execution in embedded and real-time communication environments. The neural decoder framework is designed with a lightweight transformer architecture comprising a low number of layers (e.g., six layers with 128-dimensional embeddings), which significantly reduces computational overhead compared to conventional deep-learning-based ECC decoders. Additionally, the self-attention mechanism is optimized through a learned integer-to-scalar mapping function, which reduces the need for high-dimensional matrix operations, enabling deployment on resource-constrained platforms such as edge AI devices, embedded baseband processors in 5G NR modems, satellite communication systems, low-power IoT communication chips, and FPGA/ASIC-based communication systems. The modular structure of the decoder allows integration into existing baseband processing pipelines while maintaining compatibility with multiple ECC families. Furthermore, quantization and pruning techniques may be applied to further reduce memory and power consumption, facilitating real-time decoding in wireless and IoT applications.

The proposed universal neural decoder eliminates the need for code-specific retraining, unlike prior art models that are trained individually for each ECC. Unlike ECC Transformers in the prior art, this approach introduces a code-invariant embedding scheme and a learned attention modulation mechanism based on the Tanner graph distance matrix, allowing it to generalize to unseen codes with high accuracy.

Reference is now made to FIG. 3, illustrating an end-to-end communication system based on a predetermined plurality of ECCs. According to some embodiments of the invention, a communication system utilizes a linear block code C defined by a generator matrix G∈{0,1}^{k×n} and a parity check matrix H∈{0,1}^{(n-k)×n}, wherein H satisfies the constraint GH^{T}=0 over the Galois field GF(2). The parity check matrix H defines a Tanner graph representation, comprising n variable nodes and (n−k) check nodes, wherein variable nodes correspond to encoded symbols and check nodes correspond to parity constraints.

In an embodiment, an encoder 300 receives 301 an input message m∈{0,1}^{k} and applies 302 the generator matrix G to encode the input message to a codeword x∈C⊂{0,1}ⁿ, wherein the codeword x satisfies the constraint Hx=0. The encoder 300 further modulates 303 the codeword via a Binary Phase Shift Keying (BPSK) scheme, thereby producing a transmitted signal xₛ∈{±1}ⁿ. The encoder 300 transmits 304 the transmitted signal xₛ via a Binary-Input Symmetric-Output channel, comprising an additive white Gaussian noise (AWGN) channel, to a universal decoder 305, comprising a decoder function ƒ: [symbol] ⁿ→ [symbol] ⁿ, thereby producing a channel output y=xₛ+ε, wherein ε˜ [symbol] (0, σ²Iₙ) is a random noise independent of the transmitted signal xₛ.

Optionally, the Binary-Input Symmetric-Output channel comprises one of a Rayleigh fading channel, wherein the transmitted signal xₛ experiences multipath fading, a burst-error channel, wherein errors occur in clusters rather than being uniformly distributed, or other channel in a non-Gaussian noise environment. The self-attention mechanism positively affects the adaptability of the transformer model, enabling it to learn structural relationships within the channel output y, and making it robust to different noise distributions.

Optionally, the universal decoder 305 applies a preprocessing transformation to the channel output y to ensure codeword invariance and to avoid overfitting. Optionally, the preprocessing transforms y to a codeword invariant concatenated vector \tilde{y}=h(y)=[|y|, s(y)]∈ [symbol] ^{2n-k}, wherein |y| comprises magnitude of the channel output, and s(y)=H_{yb}=H (0.5(1−sign(y)))∈{0,1}^{n-k} comprises binary code syndrome of the channel output.

Optionally, the universal decoder 305 aims to predict the equivalent multiplicative noise \tilde{ε} such that y=xₛ⊙\tilde{ε}, and to generate a soft approximation xₛ′=sign(y⊙ƒ_{θ}(|y|, Hy_{b})) of the codeword x, wherein θ is a plurality of parameters.

Reference is now made to FIG. 4, illustrating an end-to-end communication system based on a learned linear block ECC. According to some embodiments of the invention, the system implements a unified encoder-decoder training framework for binary linear block codes. The coding setting is adapted to support efficient and differentiable training of the code for end-to-end optimization over the Galois field GF(2). The system leverages a Transformer-based neural architecture in which self-attention masking is performed in a differentiable manner, enabling efficient backpropagation of code gradients. This approach facilitates the joint optimization of both encoding and decoding processes, enhancing decoding performance while also improving the design of new linear block codes.

In an embodiment, the system assumes a standard form of an ECC to enable efficient and differentiable optimization, wherein the generator matrix of the code is G=[Iₖ, P], the parity check matrix is H=[P^{T}, Iₙ₋ₖ], P∈{0,1}^{k×n-k} is the parity submatrix, and I is the identity submatrix.

Optionally, the parity submatrix P is parametrized such that P=P_{Ω}=bin(Ω), wherein Ω∈ [symbol] ^{k×n-k} is a trainable parametrized version of P, and bin: [symbol] →{0,1} is a point-wise binarization function.

Optionally, the training objective of a system comprising a neural decoder ƒ_{θ}: [symbol] ^{2n-k}→ [symbol] ⁿ, a parametrized generator matrix G_{Ω}=[Iₖ, P_{Ω}], and a parametrized parity check matrix H_{Ω}=[P_{Ω}^{T}, Iₙ₋ₖ], wherein θ is a plurality of parameters, comprises optimization of a unified end-to-end encoding-decoding process (in contrast to a standard neural decoding optimization comprising solely optimization of the decoding process), and the loss comprises:

$$ℒ ( Ω , θ ) = {𝔼}_{m ∼ B e r {n}^{k} ( 1 / 2 ) , ε ∼ 𝒵} B C E ( {f}_{θ} ( {h}_{Ω} ( {y}_{Ω} ) ) , bin ( \tilde{ε} ) ) ,$$

wherein ϕ(·,·) is a matrix multiplication over Galois field GF(2), ξ(u)=1-2u, u∈{0,1} is a bipolar mapping function, y_{Ω}=ξ(ϕ(m, G_{Ω}))+ε is a parametrized channel output, h_{Ω}(y_{Ω})=[|y_{Ω}|, H_{Ω}bin(y_{Ω})] is a parametrized codeword invariant preprocessing function, [symbol] is a channel noise distribution, BCE is the binary cross entropy loss, and \tilde{ε} is an equivalent multiplicative noise.

Optionally, optimization process of the binarization function bin comprises utilization of a straight-through estimator (STE), comprising:

$$\{ \begin{matrix}bin ( u ) = {ξ}^{- 1} ( sign ( u ) ) \\ \frac{\partial bin ( u )}{\partial u} = - \frac{{\vert u \vert \leq τ}_{}}{2}\end{matrix}$$

wherein τ is a thresholding scalar limiting the growth of the Ω weights.

Optionally, optimization process of the matrix multiplication function ϕ comprises a multilinear polynomial form, potentially inducing a saddle-point optimization, and enabling the gradient to be computed in a differentiable manner:

$${( ϕ ( m , {G}_{Ω} ) )}_{i} = {G}_{Ω} ⊕ m = {ξ}^{- 1} ( {\prod }_{j = 1}^{k} ξ ( {( {G}_{Ω} )}_{i j} \cdot {m}_{j} ) ) ∀ i ∈ \{ 1 … n \} ,$$

wherein G_{Ωi} is an i-th column of G_{Ω}, m is a binary vector, and ξ(u⊕v)=ξ(u)ξ(v) ∀u, v∈{0,1} according to differentiable equivalence mapping of XOR to sum over Galois field GF(2).

Optionally, the self-attention module comprises the following expression:

$${A}_{H} ( Q , K , V ) = softmax ( \frac{Q {K}^{T} + ψ ( g ( {H}_{Ω} ) )}{√ d} ) V$$

wherein the mask g(H_{Ω})∈ [symbol] ^{(2n-k)×(2n-k)} comprises a matrix

$$g ( {H}_{Ω} ) = ( \begin{matrix}{H}_{Ω}^{T} {H}_{Ω} & {H}_{Ω} \\ {H}_{Ω} & {H}_{Ω} {H}_{Ω}^{T}\end{matrix} ) ,$$

enabling backpropagation of a gradient ∇_{Ω} [symbol] through the self-attention modules 220 along the neural network to provide a decoder-aware code.

Optionally, an initial embedding 200Φ∈ [symbol] ^{(2n-k)×d} of the transformer model comprises Φ=[|y_{Ω}|^{T}Wₘ, W_{s(y}_{_{Ω}}₎], wherein Wₘ∈ [symbol] ^{d} is the magnitude embedding vector, and W₀∈ [symbol] ^{d}, W₁∈ [symbol] ^{d} are the two one-hot encodings of each of the n−k binary values of the syndrome embedding W_{s(y}_{_{Ω}}₎.

Optionally, the distance embedding 216 ψ_{γ}: [symbol] → [symbol] comprises a fully connected neural network with a 50-dimensional hidden layer an ReLU nonlinearities mapping each number of paths to a scalar.

Optionally, the distance embedding 216 comprises a fixed tensor at inference time.

Optionally, the output module performs the projection \hat{\tilde{ε}}=(Φ_{M}W_{M}+H_{Ω}^{T}(Φ_{S}W_{S})W_{d→1}, wherein W_{S}, W_{M}∈ [symbol] ^{d×d}, W_{d→1}∈ [symbol] ^{d} are the embedding layers, and final embedding Φ=[Φ_{M}, Φ_{S}] comprises magnitude and syndrome components.

The proposed encoder-decoder system jointly optimizes both encoding and decoding in an end-to-end differentiable manner, in contrast to prior art that separately optimizes the decoder while keeping the encoder fixed. The system leverages neural networks to co-train the generator matrix with a transformer-based decoder, resulting in improved error correction performance and reduced model size. This enables the discovery of new ECC families optimized for specific noise environments, outperforming both belief propagation decoders and conventional transformer-based decoders.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the Applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A system for decoding signals encoded with error correction codes, comprising:
a memory storing computer-readable instructions; and
at least one processor configured to execute the instructions to:
input a first error correction code, comprising a first parity check matrix, into a pre-trained model having a transformer architecture, the pre-trained model having been trained on a plurality of error correction codes;
generate a position-invariant high-dimensional representation of the first error correction code based on the pre-trained model;
incorporate relative position information into the high-dimensional representation of the first error correction code based on the first parity check matrix; and
predict a noise estimate for decoding based on the first parity check matrix and the high-dimensional representation of the first error correction code.

2. The system according to claim 1, wherein generating a position-invariant high-dimensional representation of the first error correction code comprises applying a code-invariant initial embedding based on the pre-trained model to a representation derived from the first parity check matrix.

3. The system according to claim 1, wherein incorporating relative position information into the high-dimensional representation of the first error correction code comprises:
constructing a Tanner graph from the first parity check matrix;
computing a first distance matrix from the Tanner graph; and
modulating the pre-trained model's self-attention map with the first distance matrix.

4. The system according to claim 1, wherein predicting a noise estimate for decoding comprises applying a size-invariant transformation informed by the first parity check matrix to the refined high-dimensional representation of the first error correction code.

5. The system according to claim 1, wherein the at least one processor is further configured to execute the instructions to:
receive a signal encoded with the first error correction code; and
decode the received signal, thereby generating a decoded output,
wherein decoding the received signal comprises applying the noise prediction to the received signal.

6. The system according to claim 2, wherein the code-invariant initial embedding is configured to be length-invariant.

7. The system according to claim 4, wherein the size-invariant transformation is pre-trained on the plurality of error correction codes, each error correction code in the plurality having a block length less than a predetermined threshold.

8. The system according to claim 4, wherein the size-invariant transformation comprises a learned aggregation function.

9. The system according to claim 1, wherein each of the plurality of error correction codes is a linear code.

10. The system according to claim 9, wherein a linear code is selected from the group comprising a Low-Density Parity Check (LDPC) code, a Polar code, a Reed Solomon code, and a Bose-Chaudhuri-Hocquenghem (BCH) code.

11. The system according to claim 5, wherein decoding the received signal further comprises processing the received signal using a plurality of self-attention layers and feed-forward layers, and a plurality of normalization layers.

12. The system according to claim 11, wherein decoding the received signal further comprises applying a distance embedding function, the distance embedding function being implemented as a fully connected neural network trained to learn a mapping from a number of paths in a Tanner graph to a scalar, the neural network comprising a multi-dimensional hidden layer and a plurality of nonlinear activation functions.

13. The system according to claim 11, wherein the plurality of self-attention layers and feed-forward layers comprises at least 6 layers.

14. The system according to claim 12, wherein the multi-dimensional hidden layer possesses at least 50 dimensions.

15. The system according to claim 12, wherein the plurality of nonlinear activation functions comprises a ReLU activation function.

16. The system according to claim 12, wherein the learned mapping is represented as a fixed tensor at inference time.

17. The system according to claim 1, wherein the high-dimensional representation comprises at least 128 dimensions.

18. The system according to claim 7, wherein the predetermined threshold is 150.

19. The system according to claim 1,
wherein each error correction code in the plurality of error correction codes comprises a generator matrix and a parity check matrix, and
wherein the pre-trained model was trained on the plurality of error correction codes using a plurality of differentiable masks, each differentiable mask being derived from the parity check matrix of a corresponding error correction code.

20. The system according to claim 5, wherein the noise prediction is based on one or more of the following noise models: additive white Gaussian noise, Rayleigh fading, or burst-error channels.

21. The system according to claim 1, wherein the system is applied to one or more of the following: 5G NR wireless communication networks, Wi-Fi, satellite communications, or low-power IoT devices.

22. A method for decoding a signal encoded with an error correction code, the method comprising:
inputting a first error correction code, comprising a first parity check matrix, into a pre-trained model having a transformer architecture, the pre-trained model having been trained on a plurality of error correction codes;
generating a position-invariant high-dimensional representation of the first error correction code based on the pre-trained model;
incorporating relative position information into the high-dimensional representation of the first error correction code based on the first parity check matrix; and
predicting a noise estimate for decoding based on the first parity check matrix and the high-dimensional representation of the first error correction code.
